(19) United States
(12) Patent Application Publication
(10) Pub. No.: US 2008/0083973 A1
(43) Pub. Date: Apr. 10, 2008

(54) Lead frame for an optical semiconductor device, optical semiconductor device using the same, and manufacturing method for these

(76) Inventors: Tomoyuki Yamada, Kyoto (JP); Tomohiro Futagami, Kyoto (JP); Keishiro Kawano, Kyoto (JP)

Correspondence Address: MCDERMOTT WILL & EMERY LLP, 600 13TH STREET, NW, WASHINGTON, DC, 20005-3096, US

(21) Appl. No.: 11/714,916

(22) Filed: Mar. 7, 2007

(30) Foreign Application Priority Data
Oct. 5, 2006 (JP) 2006-273810

(51) Int. Cl. H01L 33/00; H01L 21/60; H01R 43/00; H01L 23/495

(52) U.S. Cl. 257/676; 257/677; 257/99; 29/827; 438/26; 257/E33.066; 257/E21.506; 257/E23.031

(57) ABSTRACT

There is provided a lead frame for an optical semiconductor device, an optical semiconductor device using such lead frame, and a manufacturing method for these, where the optical semiconductor device exhibits favorable brightness over a long period of time by preventing discoloration and degeneration of a plating layer provide on the lead frame and a resulting reduction in a reflection coefficient for light emitted from a light emitting element, even when using silicone resin as a sealing resin. An Ag—Au alloy plating layer 22 is formed on the surface of a pure Ag plating layer 21 on a lead frame 10 sealed chloroplatinic acid-containing silicon resin, so as to prevent direct contact between the layer 21 and the silicone resin. This suppresses the formation of AgCl due to a reaction with a hardening catalyst of the silicon resin, thereby preventing the Ag plating layer from turning a blackish-brown color.

### BACKGROUND OF INVENTION

1. Field of the Invention

The present invention relates to a lead frame for an optical semiconductor device, and in particular to technology for preventing visual degradation of an optical semiconductor device in particular during emission of violet/blue light with a short wavelength (approximately 400 nm to 500 nm).

2. Related Art

Conventionally, optical semiconductor devices employing an LED element etc. as a light source are widely used as light sources in various types of display and illumination apparatuses.

Such optical semiconductor devices include, for example, a lead frame disposed on a substrate, and a light emitting element mounted on the lead frame. Thereafter, the optical semiconductor device and a periphery thereof are sealed in a sealing resin in order to prevent degredation to the light source and surrounding region due to heat, humidity, oxidation, and the like.

There is demand for the sealing resin material to have superior transparency, and furthermore maintain the high intensity of the lightsource. One example of a sealing resin material is epoxy resin. Recently there has been an increase in the need for using sealing resin in illumination apparatuses etc. that have high output and emit white light by combining the three primary colors of light. In such cases, the sealing resin material must be able to resist degradations in transparency and the emission of short wavelength light. In light of this, silicone resin is currently used due to its ability to maintain thermal resistance and optical transparency better than epoxy resin (non-patent document 1).

Also, in order to obtain superior properties of the light source, it is important to increase the luminous efficiency of the light source while effectively using the light emitted therefrom. Therefore in optical semiconductor devices, there is a technique of providing a plating layer having a superior reflection coefficient on the lead frame disposed surrounding the light source (patent document 1). Ag having a high reflection coefficient is widely used as the plating material.

Currently, various innovations have been made to optical semiconductor devices in order to provide superior performance even in white light and high output applications.

Patent document 1: Japanese Patent Application Publication No. H09-266280

Non-patent document 1: Matsushita Technical Journal Vol. 53, No. 1

However, the following problems exist with respect to optical semiconductor devices.

Specifically, upon performing reliability tests while operating optical semiconductor devices, the inventors found that a portion of the Ag plating layer surface on the lead frame sealed in silicone resin turns a blackish-brown color. It became clear that the cause for this was that, in the case of using silicone resin that includes a resin-hardening catalyst such as a metal sulfide or a metal chloride typified by chloroplatinic acid, the catalyst component reacts with Ag to form AgCl (silver chloride) or Ag₂S (silver sulfide).

When the Ag plating layer surface near the pad on which the light emitting element is mounted changes in color to a blackish-brown etc., there is a significant reduction in the reflection coefficient of the Ag plating layer. Accordingly, there is the fear that the optical semiconductor device will not be able to achieve a sufficient brightness

As noted above, there are still matters to be resolved with respect to a lead frame for an optical semiconductor device and an optical semiconductor device using the lead frame.

### SUMMARY OF INVENTION

The present invention has been achieved in light of the above problem, and aims to provide a lead frame for an optical semiconductor device, an optical semiconductor device using such lead frame, and a manufacturing method for these, where the optical semiconductor device exhibits favorable brightness over a long period of time by preventing discoloration and degeneration of a plating layer provide on the lead frame and a resulting reduction in a reflection coefficient for light emitted from a light emitting element, even when using silicone resin as a sealing resin.

In order to resolve the above problem, the present invention is a lead frame for an optical semiconductor device, the lead frame including: a metal base; and a plating layer stack that is composed of a plurality of plating layers and has been formed on at least a portion of a surface of the metal base, wherein the plating layer stack includes a pure Ag plating layer and a resistant plating layer, the resistant plating layer being a top layer of the plating layer stack and chemically resistant to at least one of a metal chloride and a metal sulfide.

Note that chemical resistance here refers to a higher resistance to the metal chloride or metal sulfide contained in the sealing resin than that of the pure Ag plating.

Here, it is desirable for the resistant plating layer to be composed of a metal having a higher standard electrode potential than Ag, such as Au. It is therefore preferable for the resistant plating layer to be an Ag—Au alloy plating layer.

Also, an intermediate plating layer composed of at least one of the group consisting of Pd, Rh, Pt, and Au may have been formed between the pure Ag plating layer and the resistant plating layer.

Furthermore, the Ag—Au alloy plating layer may include Au as a main component and Ag in a range of at least 25.0 wt % to less than 50.0 wt %.

Also, a thickness of the Ag—Au alloy plating layer may be in a range of 0.1 μm to 0.6 μm inclusive. Additionally, a thickness of the pure Ag plating layer may be in a range of 1.6 μm to 4.0 μm inclusive. Furthermore, a thickness of the intermediate plating layer may be in a range of 0.005 μm to 0.05 μm inclusive.

Also, a brilliance of the pure Ag plating layer may be at least 1.6.

Moreover, the present invention is an optical semiconductor device including: a lead frame; a light emitting element disposed on a pad portion of the lead frame; and a sealing resin sealing therein the light emitting element and the pad portion, wherein a reflection coefficient of a feed lead area of the lead frame is at least 50% with respect to light emitted from the light emitting element with a wavelength in a range of at least 400 nm to less than 500 nm, and at least 85% with respect to light emitted from the light emitting element with a wavelength in a range of at least 500 nm to less than 700 nm, the feed lead area having been sealed in the sealing resin.

Here, the lead frame may include a metal base, and a plating layer stack that is composed of a plurality of plating layers and has been formed on at least a portion of a surface of the metal base, the plating layer stack may include a pure Ag plating layer and a resistant plating layer, the resistant plating layer being a top layer of the plating layer stack and chemically resistant to at least one of a metal chloride and a metal sulfide, and the plating stack layer may exist at least in the feed lead area.

Also, the sealing resin may be an optically-transparent resin including one of a metal chloride and a metal sulfide.

Also, the optically-transparent resin may be a silicone resin, and the metal chloride may be a chloroplatinic acid.

Moreover, the present invention is a manufacturing method for a lead frame, including a plating process of forming a plating layer stack composed of a plurality of plating layers on at least a portion of a surface of a metal base, the plating process including: a first plating step of forming a pure Ag plating layer as a constituent layer of the plating layer stack; and a second plating step of forming an Ag—Au alloy plating layer as a top layer of the plating layer stack.

Here, a plating fluid including at least one of a selenium compound and an organic sulfur compound may be used in the second plating step.

Furthermore, the plating process may further include an intermediate plating layer formation step of forming an intermediate plating layer composed of at least one of the group consisting of Pd, Rh, Pt, and Au, as another constituent layer of the plating layer stack, the intermediate plating layer formation step being performed between the first plating step and the second plating step.

Also, the present invention is a manufacturing method for an optical semiconductor device, including the steps of:

mounting a light emitting element on a pad portion of a lead frame; and sealing the light emitting element and the pad portion in a sealing resin, wherein the lead frame includes a metal base, and a plating layer stack that is composed of a plurality of plating layers and has been formed on at least a portion of a surface of the metal base, the plating layer stack includes a pure Ag plating layer and a resistant plating layer, the resistant plating layer being a top layer of the plating layer stack and chemically resistant to at least one of a metal chloride and a metal sulfide, and an area of the lead frame where the plating layer stack has been formed is sealed in the sealing resin, the sealing resin being composed of a silicone resin.

According to the structures of the lead frame and optical semiconductor device of the present invention, the pure Ag plating layer, which is formed on the surface of the lead frame as a part of the plating layer stack, is covered at all times by a resistant plating layer such as the Ag—Au alloy plating layer. Therefore, in the optical semiconductor device of the present invention, when sealing resin such as silicone resin is adhered to an area of the lead frame where the plating layer stack has been formed, contact between the lone Ag component of the pure Ag plating layer and the silicone resin or other sealing resin is avoided. Such an innovation enables preventing the Ag component of the pure Ag plating layer from coming into direct contact with the resin-hardening catalyst (chloroplatinic acid) in the silicone resin.

Although the resistant plating layer comes into contact with the resin-hardening catalyst of the silicone resin etc., there is no fear of discoloration since the resistant plating layer is chemically resistant to the resin-hardening catalyst in the silicone resin.

This enables a significant improvement over conventional technology by reducing and/or suppressing the formation of AgCl or Ag₂S which causes discoloration of the surface of the lead frame of the present invention and the lead frame in the optical semiconductor device of the present invention. Hence, the favorable reflectivity of the plating layer formed on the lead frame sealed in the sealing resin can be maintained for a long period of time, even when using silicone resin as the sealing resin, thereby achieving superior brightness.

Also, using the Ag—Au alloy plating layer as the resistant plating layer results in the presence of the Au component, which is more chemically stable than Ag. The Ag component in the alloy is therefore stabilized by the Au component, thereby suppressing the reactivity that occurs with the metal chloride, metal sulfide, or other resin-hardening catalyst of the sealing resin in the case of using a pure Ag plating layer.

### BRIEF DESCRIPTION OF DRAWINGS

These and other objects, advantages, and features of the invention will become apparent from the following description thereof taken in conjunction with the accompanying drawings, which illustrate specific embodiments of the present invention.

In the drawings:

FIG. 1 is a schematic cross-sectional view of an optical semiconductor device pertaining to embodiment 1;

FIG. 2 is a cross-sectional view showing an enlarged portion of a lead frame pertaining to embodiment 1;

FIG. 3 is a cross-sectional view showing an enlarged portion of a lead frame pertaining to embodiment 2;

FIG. 4 is a cross-sectional view showing an enlarged portion of a lead frame pertaining to embodiment 3;

FIG. 5 is a cross-sectional view showing an enlarged portion of a lead frame pertaining to embodiment 4;

FIG. 6 is a cross-sectional view showing an enlarged portion of a lead frame pertaining to embodiment 5;

FIG. 7 is a cross-sectional view showing an enlarged portion of a lead frame pertaining to embodiment 6;

FIGS. 8A and 8B are used in a description of a manufacturing method for an Ag—Au alloy plating layer;

FIGS. 9A and 9B show results of a discoloration resistance test performed in a working example and a comparative example;

FIGS. 10A and 10B show results of a discoloration resistance test performed in the working example and comparative example; and

FIG. 11 shows results of a reliability test performed in another working example and comparative example.

### DETAILED DESCRIPTION OF PREFERRED EMBODIMENTS

Embodiments and working examples of the present invention are described below. It should be noted that the present invention is of course not limited to the following embodiments, and appropriate modifications can be made unless such modifications depart from the technical scope of the present invention.

### Embodiment 1

Optical Semiconductor Device Structure

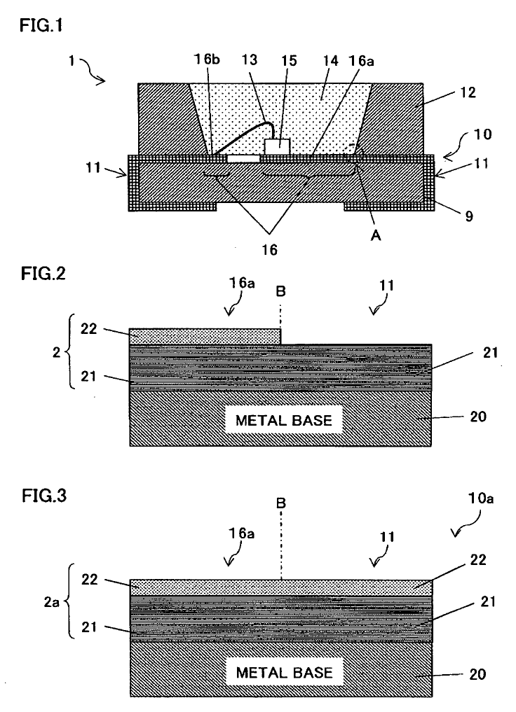

FIG. 1 is a schematic cross-sectional view of an optical semiconductor device pertaining to embodiment 1 of the present invention. FIG. 2 is a schematic cross-sectional view of a lead frame 10, showing an enlarged view of an area A of the optical semiconductor device 1. A dashed line B in FIG. 2 indicates a border between a feed lead area 16 and an external-connection lead area 11.

The optical semiconductor device 1 shown in FIG. 1 includes the lead frame 10, a peripheral resin 12, an Au wire 13 for electrical connection, a sealing resin 14, a light emitting element 15 and the like that are disposed on a substrate 9.

As shown in FIG. 2, the lead frame 10 has a basic structure in which a pure Ag plating layer 21 having a thickness of at least 1.5 μm has been formed on a surface of a plate-shaped metal base 20 that is composed of Cu, a Cu alloy, Fe, an Fe alloy etc., which have superior conductivity. Furthermore a plating layer stack 2 is formed on the feed lead area 16 of the lead frame 10 by forming an Ag—Au alloy plating layer 22 having a thickness of 0.2 μm on the pure Ag plating layer 21 for the purposes of favorable soldering of the light emitting element 15 and preventing unnecessary chemical reaction with the sealing resin.

The Ag—Au plating layer 22 includes Au as a main component and Ag in a range of at least 25.0 wt % to less than 50.0 wt %. Here, the plating layer stack 2 is assumed to have a total thickness of 1.7 μm.

In the figure, the feed lead area 16 is an area of the lead frame 10 to be sealed by the sealing resin 14. The feed lead area 16 includes a pad part 16a and a bonding part 16b. The lead frame 10 is disposed such that an area excluding the pad part 16a and bonding part 16b is the electrical-connection lead area 11. The electrical-connection lead-area 11 is separately connected to an external wiring such that external power is supplied to the light emitting element 15.

The light emitting element 15, which acts as an LED element etc., is disposed on the pad part 16a such that an upper surface of the element 15 is oriented in the light emitting direction. An end of the Au wire 13 is bonded to the bonding part 16b for electrical connection with the light emitting element 15.

The peripheral resin 12 having a mortar-shaped cross section and superior light reflecting properties is disposed surrounding the light emitting element 15. The peripheral resin 12 is formed by, for example, injection molding a polymer resin containing titanium oxide, which has superior light reflecting properties.

The sealing resin 14 is composed of a resin material having superior thermal resistance and transparency. Here, the sealing resin 14 is silicone resin, which is relatively suited for the emission of short wavelength light, in order to accommodate the light emitting properties of the light emitting element 15. The sealing resin 14 therefore includes silicone resin as the main component, and also contains an impurity-level amount of chloroplatinic acid as a resin-hardening catalyst.

Effects of Using the Lead Frame 10

In the optical semiconductor device 1 of embodiment 1 having the aforementioned structure, the Ag—Au alloy plating layer 22, which is a chemically resistant plating-layer, is formed on the surface of the pure Ag plating layer 21 in the plating layer stack 2 in the feed-lead area 16, so as to avoid direct contact between the pure Ag plating layer 21 of the lead frame 10 and the chloroplatinic acid-containing silicone resin material composing the sealing resin 14.

Compared with a conventional structure in which there is direct contact between the pure Ag plating layer 21 and the silicone resin in the feed lead area, the structure of embodiment 1 obtains the effects of significantly improving the anti-corrosion, anti-chloridization, anti-sulfidization, and anti-oxidization properties of the plating layer in the feed lead area. This therefore effectively prevents the formation of AgCl or Ag₂S, which are causes for discoloration of the lead frame 10, thereby preventing a reduction in the reflection coefficient of the light emitting element 15.

The following describes details of the principle by which such effects are obtained.

When a conventional lead frame for an optical semiconductor device is sealed in silicone resin, it is possible for the sealed area of the lead to become discolored. Such discoloration is caused by the formation of AgCl or Ag₂S due to an unnecessary chemical reaction between the Ag component of the pure Ag plating layer on the surface of the lead frame and the chloroplatinic acid compound, or other resin-hardening catalyst composed of a metal chloride or a metal sulfide, included as an impurity in the silicone resin. Here, AgCl is produced by the following process when H₂[PtCl₆].xH₂O (hexachloroplatinic acid hydrate) reacts with Ag.

H₂[PtCl₆].xH₂O→2H⁺+Pt²⁺+6Cl⁻ (Eq. 1)

Pt²⁺+2Ag→Pt+2Ag⁺ (Eq. 2)

2Ag⁺+2Cl⁻→2AgCl (Eq. 3)

Note that the resin-hardening catalyst is basically composed of chloroplatinic acid, but can have various forms such as K₂[PtCl₄] (potassium tetrachloroplatinic acid) and PtCl₂ (platinum chloride).

The reaction between Ag ions and sulfur ions in a metal sulfide occurs mainly in the following process.

2Ag⁺+S²⁻→Ag₂S (Eq. 4)

Here, when the uppermost surface plating layer of the lead frame contacting the silicone resin is a pure Ag plating layer, there is a relatively large gap in the standard electrode potentials of silver, which is 0.799 V (Ag⁺+e⁻=Ag), and platinum, which is 1.2 V (Pt²⁺+2e⁻=Pt). The existence of this gap causes a charge transfer between respective atoms, the deposition of Pt, and the promotion of Ag ionization (Eq. 2). 2Ag⁺, having heightened reaction activity force due to ionization, bonds with Cl⁻ that has dissociated from the chloroplatinic acid or the like, thereby forming AgCl (Eq. 3).

According to this process, AgCl crystals are deposited on the surface of the Ag plating-layer on the lead frame. AgCl has a blacking-brown color that absorbs visible light, thereby significantly reducing the reflection coefficient of the light emitting element 15.

In contrast, in the optical semiconductor device 1 of embodiment 1, the surface of the pure Ag plating layer 21 formed on the lead frame 10 in the sealing resin 14 is covered by the Ag—Au alloy plating layer 22. As such, there is no contact between the pure Ag plating layer and the resin-hardening catalyst, and no direct reaction forming AgCl or the like. Furthermore, pure Au, which is a very electropositive metal and is included as a component of the Ag—Au alloy, has a standard electrode potential of 1.83 V (Au⁺+e⁻=Au). The standard electrode potential of the Ag—Au alloy plating layer 22 is therefore shifted more toward pure Au than pure Ag, thereby creating a smaller potential gap with platinum than in the case of using a pure Ag plating layer. Compared with a conventional lead frame structure that uses only the pure Ag plating layer 21, the structure of embodiment 1 reduces the electromotive forces that occur in the charge transfer equation (Eq. 2), thereby effectively suppressing the formation of AgCl or Ag₂S by preventing the formation of 2Ag⁺.

Note that electropositive metals such as Au have other effects such as suppressing Cl⁻ surface adsorption. Use of the Ag—Au alloy plating layer 22 therefore reduces the adsorption of Cl⁻ to the surface thereof, which is synergistically effective in suppressing the reaction that produces AgCl.

Exemplary Manufacturing Methods for the Lead Frame 10 and the Optical Semiconductor Device 1

(1) Plating Method for the Lead Frame 10

A thin metal plate material composed of Cu, a Cu alloy, Fe, an Fe alloy etc. is pressed or etched to form the metal base 20 which includes the electrical-connection lead area 11 and the feed lead area 16. Thereafter, the Ag plating layer 21 is formed on the entire surface of the metal base 20.

Note that it is most preferable for the Ag plating method to be a known reel-to-reel method or an immersion plating method using a rack.

Next, the Ag—Au alloy plating layer is selectively formed on a portion of the Ag plating layer 21 that corresponds to the feed lead area 16. This completes the formation of the plating layer stack 2. The plating method can be performed using a masking method or the like. Specifically, it is preferable to provide a mechanical mask M formed from silicon rubber and having predetermined pattern windows 101 on a surface of a main body 100 thereof as shown in FIG. 8A, and perform the plating via the pattern windows 101 using the known sparger method shown in FIG. 8B, or a drum sparger method applying the pattern mask M.

This completes the formation of the lead frame 10.

(2) Manufacturing Method for the Optical Semiconductor Device 1

Next, the lead frame 10 is mounted on a predetermined location of the substrate 9, such that the feed lead area 16 is included in an area to be sealed in the sealing resin. Thereafter, injection molding is performed with the use of dies to form the peripheral resin 12 surrounding the feed lead area 16.

Next, the light emitting element 15 is mounted onto the pad portion 16a, and the light emitting element 15 and the bonding part 16b are connected by the Au wire 13. Then, silicone resin is filled into the interior of the peripheral resin 12 and hardened by a predetermined hardening catalyst, thereby sealing (packaging) the light emitting element 15 and the feed lead area 16.

This completes the manufacture of the optical semiconductor device 1.

The following is a description of other embodiments of the optical semiconductor device pertaining to the present invention, focusing on differences from embodiment 1.

### Embodiment 2

Structure

FIG. 3 is a schematic cross-sectional view showing a portion of a lead frame 10a of an optical semiconductor device pertaining to embodiment 2 of the present invention. The shown portion corresponds to an enlarged view of area A in FIG. 1.

A characteristic feature of the lead frame 10a is that a plating layer stack 2 is constituted from a pure Ag plating layer 21 and an Ag—Au alloy plating layer 22 that have been formed on an entire surface of one side of the lead frame 10a. The plating layers 21 and 22 have the same thicknesses as in embodiment 1.

This structure has the same effects as in embodiment 1, and the fact that the Ag—Au alloy plating layer 22 covers an entirety of one side of the lead frame 10a enables completely eliminating the danger of contact between the pure Ag plating layer 21 and the sealing resin 14, even if, for example, there are errors with respect to the disposed locations of the feed lead area 16 and the sealing resin 14. This structure is very effective in suppressing the formation of AgCl.

Manufacturing Method

Plating Method for the Lead Frame 10a

Although the overall plating method is based on the plating method of embodiment 1, in embodiment 2 it is necessary for the pure Ag plating layer 21 and the Ag—Au alloy plating layer 22 to be formed on an entire surface of the optical semiconductor device lead frame, including the external-connection lead area 11 and the feed lead area 16. Therefore, rather than using a mechanical mask as in embodiment 1, it is preferable to use a reel-to-reel plating method or an immersion plating method using a rack.

### Embodiment 3

Structure

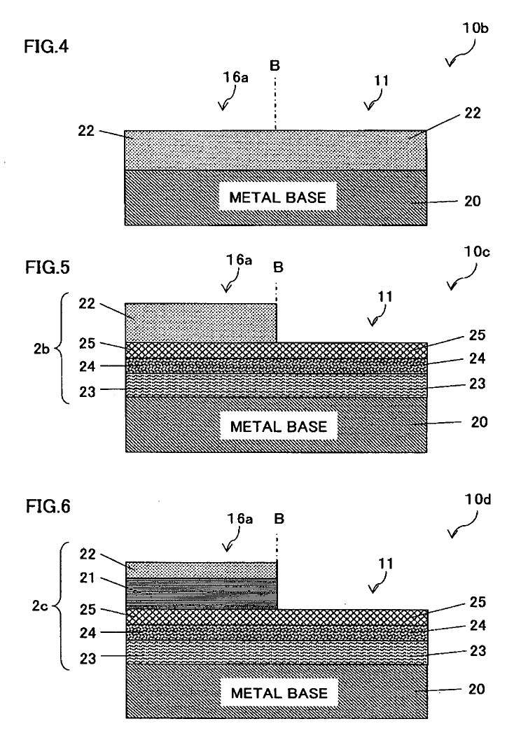

FIG. 4 is a schematic cross-sectional view showing a portion of a lead frame 10b of an optical semiconductor device pertaining to embodiment 3 of the present invention. The shown portion corresponds to an enlarged view of area A in FIG. 1.

A characteristic feature of the lead frame 10b is that the Ag—Au alloy plating layer 22 having a thickness of at least 1.5 μm has been formed directly on an entirety of one side of the metal base 20, and no pure Ag plating layer 21 has been provided. The plating method can be performed similarly to as in embodiment 2.

This structure has the same effects as embodiment 1, as well as effectively prevents contact between the pure Ag component and the sealing resin 14, even if, for example, there is partial peeling or damage to the Ag—Au alloy plating layer 22 in the feed lead area 16. This enables maintaining a superior luminous efficiency.

### Embodiment 4

Structure

FIG. 5 is a schematic cross-sectional view showing a portion of a lead frame 10c of an optical semiconductor device pertaining to embodiment 4 of the present invention. The shown portion corresponds to an enlarged view of area A in FIG. 1.

A characteristic feature of the lead frame 10c is that a plating layer stack 2b includes an Ni—Pd series plating layer (composed of an Ni plating layer 23 and a Pd plating layer 24 formed in the stated order) formed on the surface of the metal base 20 as a foundation plating layer in order for favorable solder connection using so-called lead-free solder, and an Au flash plating layer 23 and the Ag—Au alloy plating layer 22 formed thereupon.

The Ni plating layer 23, the Pd plating layer 24, and the Au flash plating layer 25 may have thickness in the respective ranges of 0.3 μm to 3.0 μm, 0.01 μm to 0.2 μm, and 0.003 μm to 0.02 μm.

Also, the Ag—Au alloy plating layer 22 has a thickness of at least 1.5 μm. Note that such thicknesses should of course not be limited to these values.

This structure has the same effects as embodiment 1, as well as has the benefit of enabling favorable electrical connection in the optical semiconductor device even when using so-called lead-free solder in response to environmental problems.

Manufacturing Method

Plating Method for the Lead Frame

The Ni plating layer 23, the Pd plating layer 24, and the Au flash plating layer 25 may be formed by, for example, a reel-to-reel plating method or an immersion plating method using a rack. Also, similarly to embodiment 1, it is preferable to form the Ag—Au alloy plating layer 22 by using the mechanical mask M, whose surface is formed from silicon rubber etc. as shown in FIG. 8A, in the sparger method shown in FIG. 8B, or a drum sparger method applying the mechanic mask M.

### Embodiment 5

Structure

FIG. 6 is a schematic cross-sectional view showing a portion of a lead frame 10d of an optical semiconductor device pertaining to embodiment 5 of the present invention. The shown portion corresponds to an enlarged view of area A in FIG. 1.

A plating layer stack 2c of embodiment 5 is basically the same as the plating layer stack 2b of embodiment 4, with the exception of a characteristic feature in that the pure Ag plating layer 21 and the Ag—Au alloy plating layer 22 are formed in the stated order on the Au flash plating layer 25. The pure Ag plating layer 21 has a thickness of 1.3 μm, and all of the other layers may have the same thicknesses as in embodiment 4. The manufacturing method for the lead frame may be performed based on the manufacturing method of embodiment 4.

### Embodiment 6

Structure

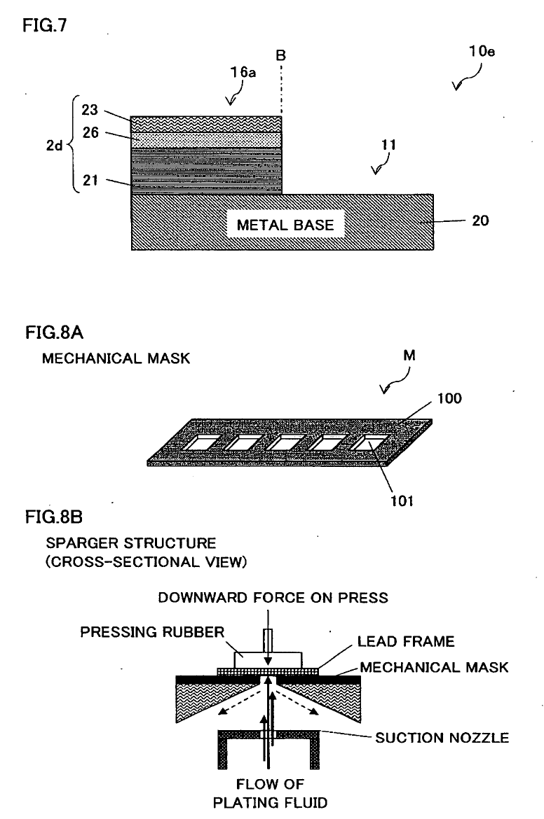

FIG. 7 is a schematic cross-sectional view showing a portion of a lead frame 10e of an optical semiconductor device pertaining to embodiment 6 of the present invention. The shown portion corresponds to an enlarged view of area A in FIG. 1.

In embodiment 6, a plating layer stack 2d constituted from three plating layers is formed on the lead frame 10e. The plating layer stack 2d is composed of first a pure Ag plating layer 21 having a brilliance of at least 1.6 and a thickness of 1.6 μm to 4.0 μm inclusive, then an intermediate plating layer 26 having a thickness of 0.005 μm to 0.05 μm inclusive and being composed of any one or more of Pd, Rh, Pt, and Au (platinum-series metal catalysts), and lastly on an Ag—Au alloy plating layer 23 having a thickness of 0.1 μm to 0.6 μm inclusive. Here, the Ag—Au alloy plating layer 23 is the top layer.

The optical semiconductor device of embodiment 6 with the above structure has the same effect as embodiment 1, that is to say, suppresses the formation of AgCl or Ag₂S due to a reaction with the catalyst for hardening the silicon resin. In particular, in the optical semiconductor device of the present embodiment, the lead frame 10e is provided with the intermediate plating layer 26 composed of a high performance platinum-series metal catalyst, thereby obtaining the effect of further stabilizing the Ag component, which has a relatively high ionization tendency. Compared to the other embodiments, this more effectively prevents the formation of AgCl or Ag₂S, and achieves superior luminous efficiency for a long period of time.

Also, the surface of the bottom-most pure Ag plating layer 21 has a brilliance of at least 1.6 according to JIS standards. This achieves the effect of an improved reflection coefficient. Note that although the intermediate plating layer 26 and the Ag—Au alloy plating layer 22 are formed on the pure Ag plating layer 21, visible light can reach the pure Ag plating layer 21 since the layers 26 and 22 are very thin. Accordingly an improvement in the reflection coefficient can be effectively achieved even if the pure Ag plating layer 21 is the bottom-most layer.

Specifically, in the case of using the pure Ag plating layer 21 having a brilliance of at least 1.6, there is an improvement in the reflection coefficient for visible light with wavelengths in the range of 400 nm to 700 nm inclusive, and in particular, a reflection coefficient of at least 80% can be achieved for light with a wavelength of around 450 nm. Also, it was found that a high reflection coefficient of at least 85% can be achieved for visible light with wavelengths in the range of 500 nm to 700 nm inclusive.

Note that the pure Ag plating layer 21 is not limited to embodiment 6, but instead may be adjusted to have a brilliance of at least 1.6 according to JIS standards in the other embodiments 1 to 5. Similarly, the intermediate plating layer 26 may be applied in the other embodiments as well.

Also, the plating layer stack 2d may be formed on an entirety of one side of the lead frame 10e.

Manufacturing Method

A plating method using, for example, a silver cyanide plating fluid can be used to form the pure Ag plating layer 21 having a brilliance of at least 1.6. As another method of obtaining the same brilliance, it is desirable to add a silver cyanide plating gloss agent containing selenium and a sulfur-series organic compound, in an amount of 20 cc to 50 cc per 1 liter of plating fluid.

### Comparative Performance Experiment 1

Next, a working example of the lead frame and a comparative example were manufactured, and a comparative performance test was performed to confirm the effects of the present invention.

First, a pure Ag plating layer having a brilliance of 1.7 and a thickness of 2.0 mm was formed on the surface of a metal base formed by pressing a copper alloy material. Next, a Pd plating layer having a thickness of 0.015 μm was formed thereon, and an Ag—Au alloy plating layer with a thickness of 0.2 μm and including Au as a main component 35.0 wt % of Ag was formed on an entire surface of the Pd plating layer. This completed the working example of the lead frame.

Also, the comparative example of the lead frame was formed by providing a semigloss pure Ag plating layer with a brilliance of 0.3 on the surface of a metal base.

First Evaluation Test

First, an anti-discoloration test was performed using an ammonium sulfide solution.

The test was performed by heating the lead frame of the working example and the lead frame of the comparative example on a hot plate at 300° C. for one minute. This heating was performed to simulate thermal history in an assembly step for the optical semiconductor device.

The ammonium sulfide solution (0.2 ml/L ammonium sulfide aqueous solution) was prepared based on the anti-discoloration test method of JIS standard H8621, and the heated comparative example lead frame and working example lead frame were immersed for five minutes while stirring the solution. The lead frames were then sufficiently flushed with water and dried.

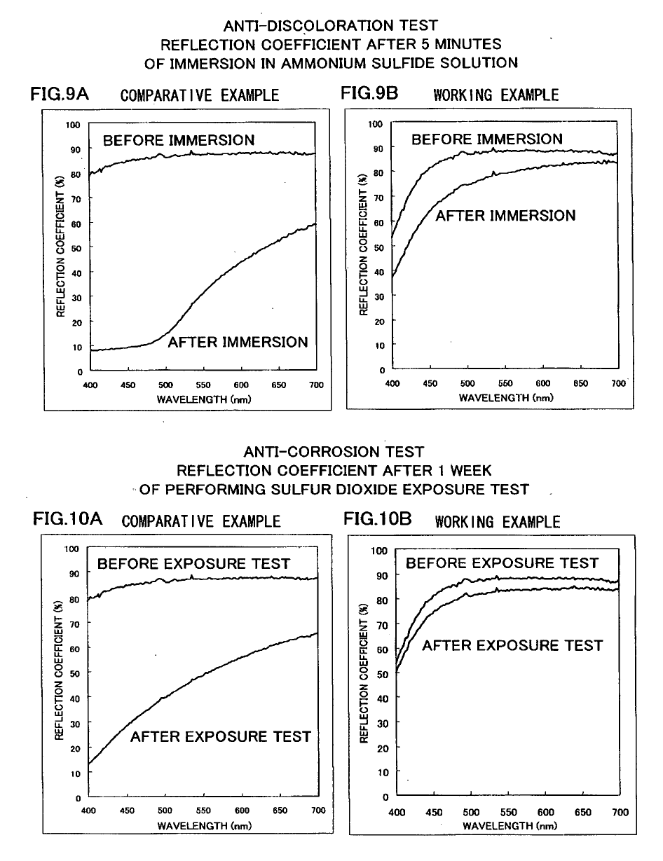

FIGS. 9A and 9B show results of the reflection coefficient evaluation after performing the anti-discoloration test. FIG. 9A corresponds to the comparative example, and FIG. 9B corresponds to the working example.

As shown in FIG. 9A, the reflection coefficient of the comparative example, in particular with respect to light with a wavelength of around 450 nm, fell drastically from around 85% to around 10%. In contrast, as shown in FIG. 9B, the reflection coefficient of the working example fell from around 80% to about 65%. It was therefore confirmed that the working example has a dramatically better anti-discoloration property than the comparative example.

Second Evaluation Test

Next, an anti-corrosion test was performed using sulfur dioxide gas.

The testing method was configured similarly to that of the first evaluation test, and an exposure test was performed based on the sulfur dioxide gas test specified in JIS standard H8502. Specifically, the conditions for the test were a sulfur dioxide gas concentration of 25 ppm, a temperature of 40° C., a relative humidity of 80%, and an exposure time of 168 hours (one week).

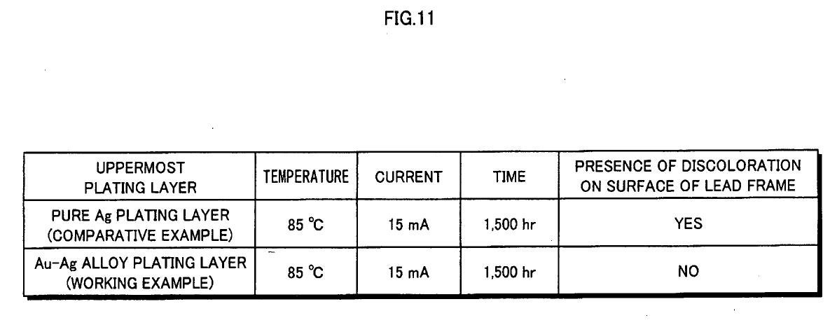

FIGS. 10A and 10B show results of measuring the reflection coefficients of the comparative example lead frame and the working example lead frame respectively. As shown in FIG. 10A, the reflection coefficient of the comparative example, with respect to light with a wavelength of around 450 nm, fell from around 85% to around 30%. In contrast, as shown in FIG. 10B, the reflection coefficient of the working example, with respect to light with a wavelength of around 450 nm, fell from 80% only down to 75%. Similarly to the first evaluation test, it was confirmed that the working example has a dramatically better anti-corrosion property than the comparative example.

### Comparative Performance Experiment 2

Next, the inventors tested for the presence of discoloration in lead frames in a case of sealing the lead frames in silicone resin.

Another comparative example and working example of the optical semiconductor device were manufactured. Specifically, the working example was manufactured as follows. A lead frame was formed by pressing a Cu alloy material, a pure Ag plating layer with a thickness of 2 μm was formed thereon by an Ag plating process, and an Ag—Au alloy plating layer containing Au as a main component and 35.0 wt % of Ag and having a thickness of 0.3 μm was formed on an entire surface of the pure Ag plating layer. Next, peripheral resin was molded around the lead frame. Then, a light emitting elements was mounted on a pad portion of the lead frame with use of Ag paste, and the light emitting element was connected to a connection portion of a feed lead by bonding of an Au wire. Finally, silicone resin including chloroplatinic acid as a resin-hardening catalyst was filled into the space surrounded by the peripheral resin to seal the light emitting element and the like. This completed the manufacture of the working example of the optical semiconductor device.

The comparative example of the optical semiconductor device was manufactured by forming a pure Ag plating layer having a thickness of 2.0 μm on a lead frame.

A reliability test was performed by continuously operating the working example and comparative example optical semiconductor devices for 1,500 hours. The conditions of the reliability test were a temperature load of 85° C. and a current of 15 mA. FIG. 11 shows results of the reliability test.

As shown in FIG. 11, no blackish-brown discoloration was seen on the surface of the lead frame in the working example, nor was there a drop in the brightness thereof. On the other hand, discoloration of the lead frame in the comparative example was confirmed, and there was also a drop in brightness. As such, it can be said that the confirmed favorable performance of the working example is due to the Au component of the Ag—Au alloy plating layer, that was formed on the surface of the lead frame, stabilizing Ag with respect to the hardening catalyst in the silicone resin, thereby suppressing the formation of AgCl which causes discoloration.

The superiority of the present invention was confirmed by the aforementioned experiments.

Note that the present invention is industrially applicable as technology for improving brightness with respect to white light or blue/violet light emitted by an optical semiconductor device used for, for example, illumination.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. A lead frame for an optical semiconductor device, the lead frame comprising:
a metal base; and
a plating layer stack that is composed of a plurality of plating layers and has been formed on at least a portion of a surface of the metal base, wherein
the plating layer stack includes a pure Ag plating layer and a resistant plating layer, the resistant plating layer being a top layer of the plating layer stack and chemically resistant to at least one of a metal chloride and a metal sulfide.

2. The lead frame for the optical semiconductor-device of claim 1, wherein
the resistant plating layer is an Ag—Au alloy plating layer.

3. The lead frame for the optical semiconductor device of claim 1, wherein
an intermediate plating layer composed of at least one of the group consisting of Pd, Rh, Pt, and Au has been formed between the pure Ag plating layer and the resistant plating layer.

4. The lead frame for the optical semiconductor device of claim 2, wherein
the Ag—Au alloy plating layer includes Au as a main component and Ag in a range of at least 25.0 wt % to less than 50.0 wt %.

5. The lead frame for the optical semiconductor device of claim 1, wherein
a thickness of the Ag—Au alloy plating layer is in a range of 0.1 μm to 0.6 μm inclusive.

6. The lead frame for the optical semiconductor device of claim 1, wherein
a thickness of the pure Ag plating layer is in a range of 1.6 μm to 4.0 μm inclusive.

7. The lead frame for the optical semiconductor device of claim 3, wherein
a thickness of the intermediate plating layer is in a range of 0.005 μm to 0.05 μm inclusive.

8. The lead frame for the optical semiconductor device of claim 1, wherein
a brilliance of the pure Ag plating layer is at least 1.6.

9. An optical semiconductor device comprising:
a lead frame;
a light emitting element disposed on a pad portion of the lead frame; and
a sealing resin sealing therein the light emitting element and the pad portion, wherein
a reflection coefficient of a feed lead area of the lead frame is at least 50% with respect to light emitted from the light emitting element with a wavelength in a range of at least 400 nm to less than 500 nm, and at least 85% with respect to light emitted from the light emitting element with a wavelength in a range of at least 500 nm to less than 700 nm, the feed lead area having been sealed in the sealing resin.

10. The optical semiconductor device of claim 9, wherein
the lead frame includes a metal base, and a plating layer stack that is composed of a plurality of plating layers and has been formed on at least a portion of a surface of the metal base,
the plating layer stack includes a pure Ag plating layer and a resistant plating layer, the resistant plating layer being a top layer of the plating layer stack and chemically resistant to at least one of a metal chloride and a metal sulfide, and
the plating stack layer exists at least in the feed lead area.

11. The optical semiconductor device of claim 9, wherein
the sealing resin is an optically-transparent resin including one of a metal chloride and a metal sulfide.

12. The optical semiconductor device of claim 11, wherein
the optically-transparent resin is a silicone resin.

13. The optical semiconductor device of claim 9, wherein
the metal chloride is a chloroplatinic acid.

14. A manufacturing method for a lead frame, including a plating process of forming a plating layer stack composed of a plurality of plating layers on at least a portion of a surface of a metal base, the plating process comprising:
a first plating step of forming a pure Ag plating layer as a constituent layer of the plating layer stack; and
a second plating step of forming an Ag—Au alloy plating layer as a top layer of the plating layer stack.

15. The manufacturing method for the lead frame of claim 14, wherein
a plating fluid including at least one of a selenium compound and an organic sulfur compound is used in the second plating step.

16. The manufacturing method for the lead frame of claim 14, wherein
the plating process further comprises
an intermediate plating layer formation step of forming an intermediate plating layer composed of at least one of the group consisting of Pd, Rh, Pt, and Au, as another constituent layer of the plating layer stack, the intermediate plating layer formation step being performed between the first plating step and the second plating step.

17. A manufacturing method for an optical semiconductor device, comprising the steps of:
mounting a light emitting element on a pad portion of a lead frame; and
sealing the light emitting element and the pad portion in a sealing resin, wherein
the lead frame includes a metal base, and a plating layer stack that is composed of a plurality of plating layers and has been formed on at least a portion of a surface of the metal base,
the plating layer stack includes a pure Ag plating layer and a resistant plating layer, the resistant plating layer being a top layer of the plating layer stack and chemically resistant to at least one of a metal chloride and a metal sulfide, and
an area of the lead frame where the plating layer stack has been formed is sealed in the sealing resin, the sealing resin being composed of a silicone resin.
